(19) United States
(12) Patent Application Publication
(10) Pub. No.: US 2008/0197869 A1
(43) Pub. Date: Aug. 21, 2008

(54) ELECTRICAL CONNECTING APPARATUS

(75) Inventors: Yuji MIYAGI, Aomori (JP); Hitoshi SATO, Aomori (JP); Kiyotoshi MIURA, Aomori (JP)

Correspondence Address: INGRASSIA FISHER & LORENZ, P.C., 7010 E. COCHISE ROAD, SCOTTSDALE, AZ, 85253, US

(73) Assignee: KABUSHIKI KAISHA NIHON MICRONICS, Tokyo (JP)

(21) Appl. No.: 12/025,631

(22) Filed: Feb. 4, 2008

(30) Foreign Application Priority Data
Feb. 19, 2007 (JP) 2007-038252

(51) Int. Cl. G01R 1/067

(52) U.S. Cl. 324/762

(57) ABSTRACT

To restrain misregistration of tips due to change in temperature, an electrical connecting apparatus is used for connection of a tester, and electrical connection terminals of a device under test to undergo electrical test by the tester. The electrical connecting apparatus comprises a probe board having a plurality of probe lands on its underside; and a plurality of contacts having tip portions to be brought into contact with a base end portion fixed at the respective probe lands and the connection terminals of the device under test. The measure from the tip of each contact and the probe land ranges from 1.1 to 1.3 mm, and the coefficient of thermal expansion of the probe board is greater than the coefficient of thermal expansion of the device under test within the range from 1 to 2 ppm/° C.

### TECHNICAL FIELD

The present invention relates to an electrical connecting apparatus for connecting a tester and an electrical connection terminal of a device under test to undergo an electrical test by the tester.

### BACKGROUND

An electrical performance test, (i.e., inspection or measurement test) of a device under test such as a semiconductor integrated circuit is conducted by use of an electrical connecting apparatus such as a probe card provided in a tester.

There is an electrical connecting apparatus of this type in which a plurality of contacts (i.e., probes) to be brought into contact with a connection terminal (i.e., electrode) of the device under test are disposed on the underside of a probe board, a wiring board is disposed above the probe board, an electrical connector (i.e., socket device) is disposed between the probe board and the wiring board to connect a wiring circuit provided on the wiring board and a wiring circuit provided on the probe board (Patent Document 1).

Patent Document 1; WO2005/106504

In this electrical connecting apparatus, each contact has a vertical crank-shaped form with a base end portion fixed on the underside of the probe board, an arm portion extending laterally from the lower end portion of the base end portion and a tip portion projected downward from the arm portion.

The electrical connecting apparatus using such contacts supplies power to a device under test through the contacts while pressing the tip (front end) of each contact against the connection terminal of the device under test, and conduct an test of the device under test by introducing a signal from the device under test into the tester through the contact.

In inspecting, each contact elastically deforms at the arm portion into an arc shape due to an overdrive acting on the contact, thereby scraping away an oxide film on the surface of the electrode (i.e., connection terminal) of the device under test.

Recently, the electrical connecting apparatus of this type are required to be large-sized so as to enable to inspect while maintaining the temperature of the device under test at an arbitrary value between a low temperature of about −40° C. and a high temperature of about +150° C. and, for shortening an test time, to collectively inspect simultaneously multiple devices under test on a wafer by enhancing an arrangement density of the contacts.

In a conventional electrical connecting apparatus, however, by changing the temperature of a device under test, for example, when the temperature of the device under test is raised, the temperature of the electrical connecting apparatus rises due to heat from a device under test, which causes thermal expansion in the apparatus. As a result, an arrangement pitch of contacts is changed greatly, thereby creating a so-called misregistration (i.e., displacement) wherein tips are shifted relative to the contact terminals of the device under test.

The larger the electrical connecting apparatus becomes, the greater such thermal expansion and misregistration of the tips become. Also, the higher the arrangement density of the contacts is, the higher the ratio of the amount of displacement of the tips to the arrangement pitch of the connection terminals of the device under test is.

As mentioned above, when the amount of displacement of the tips to the connection terminals of the device under test becomes larger, there appear cases where the tips do not contact the connection terminals of the device under test, thereby disabling an accurate test.

Such displacement of the tips due to change in temperature occurs likewise when the temperature of the device under test is lowered.

### BRIEF SUMMARY

### Problem to Be Solved

An object of the present invention is to prevent displacement of the probes due to change in temperature.

### Means to Solve Problem

The electrical connecting apparatus according to the present invention electrically connects a tester to an electrical connection terminals of a device under test to undergo an electrical test by the tester. The electrical connecting apparatus comprises: a probe board having a plurality of probe lands on the underside; and a plurality of contacts provided with a base end portion fixed on the probe lands, and a tip portion to be brought into contact with the connection terminal of the device under test. The distance (i.e., measure) from the tip of each contact to the probe land ranges form 1.1 to 1.3 mm, and the coefficient of thermal expansion of the probe board is greater than the coefficient of thermal expansion of the device under test within the range from 1 to 2 ppm/° C.

The contact may be further provided with an arm portion extending laterally from the lower end of the base end portion, and wherein each tip portion of the contacts may be projected downward from the arm portion.

The electrical connecting apparatus further comprises: a wiring board having a plurality of wiring circuits to be connected to the tester; an electrical connector disposed on the underside of the wiring board; and a support member disposed on the upside of the wiring board. The probe board may be disposed on the underside of the electrical connector. The electrical connector may be provided with an electrical insulating plate disposed on the underside of the wiring board and a plurality of connecting members disposed on the electrical insulating plate to electrically connect the wiring circuit and the contact.

The thermal expansion rate of the probe board can be set within a range of from 3 to 5 ppm/° C. when the coefficient of thermal expansion of the device under test is from 2 to 3 ppm/° C.

In the electrical connecting apparatus according to the present invention, the distance from the tip of each contact to the probe land is set at from 1.1 mm to 1.3 mm. Consequently, according to the present invention, a gap for communicating a space between the probe board and the device under test, that is, a gap for permitting the air to move is formed in a state that the tip is pressed against the connection terminal of the device under test.

Thus, even if the device under test is heated or cooled, the probe board is cooled or heated by the moving air, and the thermal expansion rate of the probe board is greater than that of the device under test by from 1 ppm/° C. to 2 ppm/° C., so that misregistration of the tip of the contact relative to the connection terminal of the device under test is restrained, thereby preventing the tip of the contact from detaching from the connection terminal of the device under test to enable an accurate test.

If the distance from the tip of the contact to the probe land is as short as less than 1.1 mm, when an overdrive acts on the contact, the contact is brought into contact particularly with the probe board or the probe land, or a foreign matter is trapped between the contact and the probe board, thereby failing to obtain the intended stable electrical contact.

If the distance from the tip of the contact to the probe land exceeds 1.3 mm, when fixing the contact to the probe land or at the time of use of the electrical connecting apparatus, a problem to make an initial purpose of the contact difficult arises, so that positioning of the probes, particularly the tips, becomes less accurate.

From the above viewpoint, in an electrical connecting apparatus using contacts enabling a small pitch alignment and a high density alignment, the distance from the tip of the contact to the probe land is preferably from 1.1 mm to 1.3 mm.

If the coefficient of thermal expansion of the probe board is less than that of the device under test by 1 ppm/° C., when an overdrive acts on the contact, the contact is brought into contact with the probe board (particularly probe land), or a foreign matter is trapped between the probe board and the contact, so that the contact does not display a sufficient function as an elastic body and the intended stable electrical contact cannot be obtained. If the coefficient of thermal expansion of the probe board is greater than that of the device under test 2 ppm/° C., it becomes difficult for the contact to achieve an initial purpose because the alignment of the contacts in attaching the contact to the probe board and in using the contact becomes less accurate.

### BRIEF DESCRIPTION OF THE DRAWINGS

FIG. 1 is a front elevation partly showing in section of one embodiment of the electrical connecting apparatus according to the present invention.

FIG. 2 is a schematic view showing the contact of the electrical connecting apparatus in FIG. 1 in a state of being pressed against the device under test.

FIG. 3 is a bottom view of the electrical connecting apparatus shown in FIG. 1.

FIG. 4 is a front elevation of the contact using the electrical connecting apparatus shown in FIG. 1.

FIG. 5A is a schematic view showing a relative position of the tip of the contact to the connection terminal of the device under test when the temperature of the device under test is maintained at −40° C.

FIG. 5B is a schematic view showing a relative position of the tip of the contact to the connection terminal of the device under test when the temperature of the device under test is maintained at +23° C.

FIG. 5C is a schematic view showing a relative position of the tip of the contact to the connection terminal of the device under test when the temperature of the device under test is maintained at +150° C.

FIG. 6 is a graph showing the relation between the temperature of the device under test and the temperature of the probe board.

### EXPLANATION OF REFERENCE NUMERALS

10 electrical connecting apparatus

12 device under test

14 electrical connection terminal of device under test

20 support member

22 wiring board

24 electrical connector

26 probeboard

26b probe land

28 base ring

30 fixed ring

32 thermal deformation restraining member

40 electrical insulting plate

44 connecting pin

46 contact

48 base end portion of contact

50 arm portion of contact

54 tip of contact

### DETAILED DESCRIPTION OF A PREFERRED EMBODIMENT

### Explanation of Terms

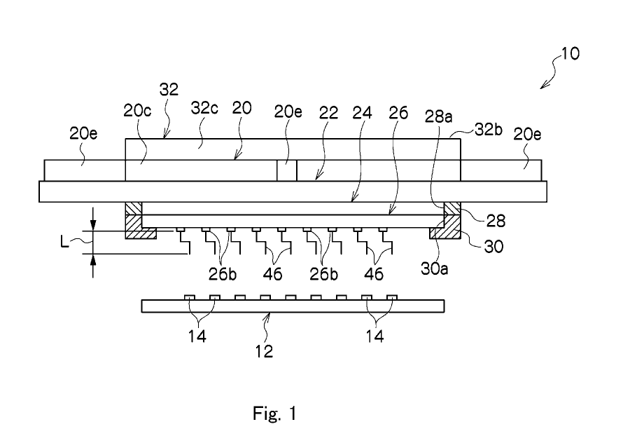

In the present invention, the vertical direction means the up-and-down direction in FIG. 1. The so-called vertical direction in the present invention, however, differs depending on the attitude of the device under test relative to the tester at the time of test (i.e., inspection). Consequently, the vertical direction in the present invention may be determined to be the up-and-down direction, the reverse direction, the horizontal direction or an inclined direction with an inclination to the horizontal direction according to an actual testing apparatus.

### Embodiment

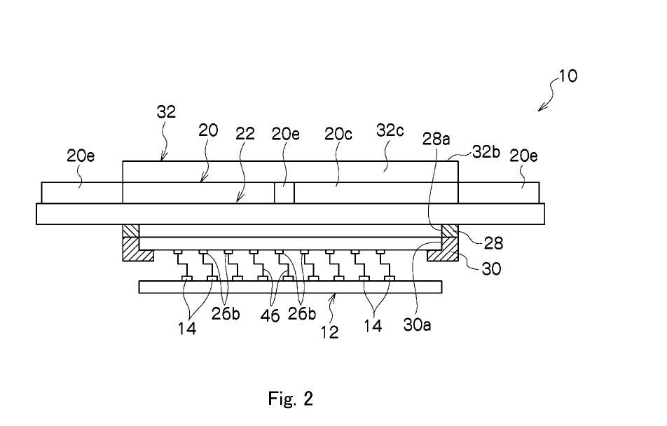

Referring to FIGS. 1 through 3, the electrical connecting apparatus 10 is disposed in a tester (not shown) for testing an integrated circuit as a device under test 12. The device under test 12 may be at least one integrated circuit cut from a wafer, or at least one integrated circuit within an uncut wafer. In either case, the device under test 12 has a plurality of electrical connection terminals 14 such as electrode pads on the upside.

As shown in FIG. 1, the connecting apparatus 10 comprises: a flat plate-like support member 20 as viewed from the front side; a circular flat plate-like wiring board 22 held on the underside of the support member 20; a flat plate-like electrical connector 24 disposed on the underside of the wiring board 22; a flat plate-like probe board 26 disposed on the underside of the electrical connector 24; a base ring 28 in which a rectangular or circular central opening 28a for receiving the electrical connector 24 is formed; and a fixed ring 30 for sandwiching the edge portion of the probe board 26 in cooperation with the edge portion around the central opening 28a of the base ring 28.

As described later, the above members 20 to 30 are integrally assembled by a plurality of screw members.

As shown in FIGS. 1 through 3, the support member 20 is made of a metal material such as a stainless steel plate like a frame in a flat-plate-like shape when seen from the front side, but is shaped like a control handle of a ship when seen from above. The support member 20 is disposed on the upside of the wiring board 22 with its underside abutted on the upside of the wiring board 22.

The support member 20 may have, for instance, an annular portion 20c, a plurality of joint portions (not shown) extending from the inside of the annular portion 20c toward the center and integrally joined with each other at the central portion of the annular portion 20c, and a plurality of extension portions 20e extending from the outside of the annular portion 20c radially outward. A combination of the annular portion 20c and joint portion (not shown) has a shape like a wheel of a two-wheeled cart.

In the illustrated example, a thermal deformation restraining member 32 for restraining thermal deformation of the support member 20 is disposed on the upside of the support member 20. The thermal restraining member 32 is made of a material such as aluminum which has a coefficient of thermal expansion (particularly coefficient of linear expansion) as great as or 1 ppm/° C. to 2 ppm/° C. greater than that of the support member 20, and is shaped like a ring substantially as large as the annular portion 20c of the support member 20.

The thermal deformation restraining member 32 has the same shape as that of the combination of the annual portion 20c and the joint portion of the support member 20. Therefore, the thermal deformation restraining member 32 also has an annular portion 32c and a joint portion not shown.

The thermal deformation restraining member 32 is assembled into the upside of the annular portion 20c of the support member 20 at its own annular portion 32c by a plurality of screw members so as to cover the upside of the annular portion 20c of the support member 20 such that the underside of its own annular portion 32c abuts the upside of the annular portion 20c of the support member 20.

The wiring board 22, in the illustration, is made of an electrical insulating resin such as polyimide resin into a circular plate. In the annular peripheral portion on the upside of the wiring board 22, a plurality of connectors (not shown) to be connected to the electric circuit of the tester are arranged annularly. Each connector has a plurality of terminals (not shown).

The wiring board 22 has a plurality of wiring circuits (not shown) in the inside. Each wiring circuit is connected to a corresponding terminal at one end portion in correspondence to a terminal of the connector. The other end portion of each wiring circuit of the wiring board 22 is exposed at the central portion of the underside of the wiring board 22, to form a plurality of electrical connection terminals (not shown) in correspondence to the respective terminals of the connectors. The connection terminals of the wiring board 22 are arranged in a rectangular or circular matrix form.

A plurality of relays (not shown) for changing over the connection terminals of the wiring board 22 to be connected to the terminals of the connector or for disconnecting the wiring circuits of the wiring board 22 from the connector in an emergency may be arranged at the central portion of the upside of the wiring board 22.

The terminals of the connector and the connection terminals of the wiring board 22 are properly connectable to each other through the wiring circuits of the wiring board 22 and the relays. The connector can be disposed in a space more outward from the annular portions 20c and 32c of the support member 20 and the thermal deformation restraining member 32, and the relays can be disposed in a space more inward from the annular portions 20c and 32c of the support board 20 and the thermal deformation restraining member 32.

The electrical connector 24 can include: an electrically insulating plate made of an electrical insulating material such as polyimide resin into a rectangular or circular shape having a size to be received in the central opening 28a of the base ring 28; a plurality of through holes (not shown) formed on the electrical insulating plate so as to penetrate it in its thickness direction and made to correspond to the respective connection terminals of the wiring board 22; and an electrically conductive connection pin disposed in each through hole so as not to drop off.

Each through hole of the electrical insulating board 40 has a circular sectional configuration. Each connection pin is supported on the electrical insulating board 40 so as not to drop off. Each connection pin may be a so-called pogo pin.

The foregoing pogo pin can include: a cylindrical member; a first pin member disposed at one end portion of the cylindrical member so as to move longitudinally of the cylindrical member; a second pin member disposed at the other end portion of the cylindrical member so as to move longitudinally of the cylindrical member; and a compression coil spring disposed between the first and the second pin members within the cylindrical member to energize the first and the second pin members in the directions that the respective front end portions are projected from the one end portion and the other end portion of the cylindrical member (that is, in the directions that the first and the second pin members are away from each other).

The pogo pins as mentioned above are held in the through holes of the electrical insulating plate 40 in the cylindrical member so as not to drop off, the first and the second pin members being held on the cylindrical member not to drop off.

The upper end of each connection pin is brought into contact with the connection terminal (not shown) provided on the underside of the wiring board 22, and the lower end of each connection pin is brought into contact with the electrical connection terminal (not shown) formed on the upside of the probe board 26 in correspondence to the connection terminal of the wiring board 22. Thus, each of the connection pins electrically connects the connection terminals of the wiring board 22 to the connection terminals of the probe board 26 in one-to-one relationship.

The base ring 28 is attached to the underside of the wiring board 22. The central opening 28a of the base ring 28 is somewhat larger than the electrical connector 24.

The fixed ring 30 has at its central portion a central opening 30a which permits the contact 46 of the probe board 26 to be exposed. The lower end portion of the central opening 30a is smaller than the probe board 26, but the remaining portion upper than the lower end portion of the central opening 30a has a size enough to receive the probe board 26. The central opening 30a has a rectangular or a circular shape.

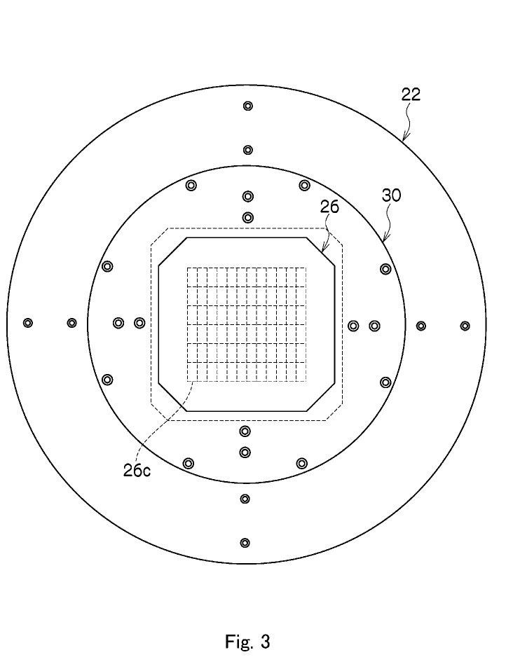

The probe board 26 is provided with a ceramic plate and a multilayer interconnection board laminated on the ceramic plate. The multilayer interconnection board is made of an electrical insulating material such as a polyimide resin. The probe board 26 has a rectangular or a circular shape of approximately the same size as the electrical insulating plate of the electrical connector 24. The probe board 26 has on a contact area 26c (see FIG. 3) of the underside thereof a plurality of probe lands 26b to which the contacts 46 are attached. The connection terminals provided on the upside of the probe board 26 and the probe lands 26b are electrically connected in one-to-one relationship by the wiring circuits formed within the probe board 26.

The probe board 26 such as above can be formed by a ceramic board member (not shown) and a multilayer interconnection board formed on the underside of the ceramic board member. In such a case, the connection terminals formed on the upside of the probe board 26 are provided on the upside of the ceramic board member, and the probe lands 26b are provided on the underside of the multilayer interconnection board.

The coefficient of thermal expansion of the probe board 26 is greater than that of the device under test 12 by the range from 1 ppm/° C. to 2 ppm/° C. For this reason, when the coefficient of thermal expansion of the device under test 12 is rang from 2 ppm/° C. to 3 ppm/° C., the coefficient of thermal expansion of the probe board 26 can range from 3 ppm/° C. to 5 ppm/° C.

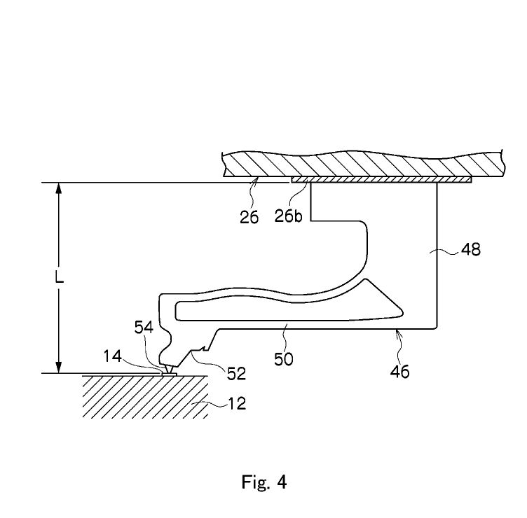

Each contact 46 is of a cantilever type having substantially a vertical shape by the base end portion 48, the arm portion 50 and the tip portion 52, including, as shown in FIG. 4. The base end portion 48 is fixed at the probe land 26b of the probe board 26 and extending vertically. The arm portion 50 extends laterally from the lower end portion of the base end portion 48. The tip portion 52 projects downward from the arm portion 50.

Each contact 46 is fixed on the probe land 26b with its tip 54 projected downward, by means of adhesion with an electrical conducting adhesion or technique such as welding by laser at the upper end portion of the base end portion 48. Thus, the respective contacts 46 are electrically connected to the corresponding connection terminals of the wiring board 22 through the wiring circuits of the probe board 26 and the connection pins of the electrical connector 24 in one-to-one relationship.

The distance (i.e., measure) L from the tip of each contact 46 to the probe land ranges from 1.1 mm to 1.3 mm.

The electrical connecting apparatus 10 is assembled by a plurality of screw members in the following manner.

The thermal deformation restraining member 32 is attached to the upside of the annular portion 20c by a plurality of male screw members penetrating the thermal deformation restraining member 32 from above downward to be screwed into the annular portion 20c of the support member 20.

The electrical connector 24 is attached to the annular portion 20c with a plurality of male screw members screwed into the annular portion 20c of the support member 20 to penetrate the electrical connector 24 and the wiring board 22 from below upward. These male screw members, with their front ends screwed into the annular portion 20c of the support member 20, has an action to sandwich the wiring board 22 between the electrical connector 24 and the support member 20.

The base ring 28 and the fixed ring 30 are combined with each other so as to sandwich the edge portion of the probe board 26 with a plurality of male screw members screwed into the base ring 28 to penetrate the fixed ring 30 from below upward.

The base ring 28 is attached to the support member 20 by a plurality of male screw members screwed into the base ring 28, penetrating the inward annular portion 20b of the support member 20 and the wiring board 22 from above downward.

The contact 46 provided in each probe land 26b in a state of being assembled into the electrical connecting apparatus 10 is electrically connected to the corresponding connection terminal of the wiring board 22. As a result, when the front end of the contact 46 abuts on the connection terminal of the device under test 12, the connection terminal of the device under test 12 is connected to the tester via the corresponding connector 36 to undergo test of the electric circuit by the tester.

While the illustration only shows a few contacts 46, actually multiple contacts 46 are provided depending on the device under test 12. For instance, in case where a plurality of uncut integrated circuits on a semiconductor wafer are to be inspected at a time or several times collectively at the same time, there are provided as many contacts as required for a single application of electricity.

In the electrical connecting apparatus 10, during test, the tip 54 of each contact 46 is pressed against the connection terminal 14 of the device under test 12 which undergoes test in that state. Also, the temperature of the device under test 12 is maintained at an arbitrary value from a low temperature around −40° C. to a high temperature around +150° C.

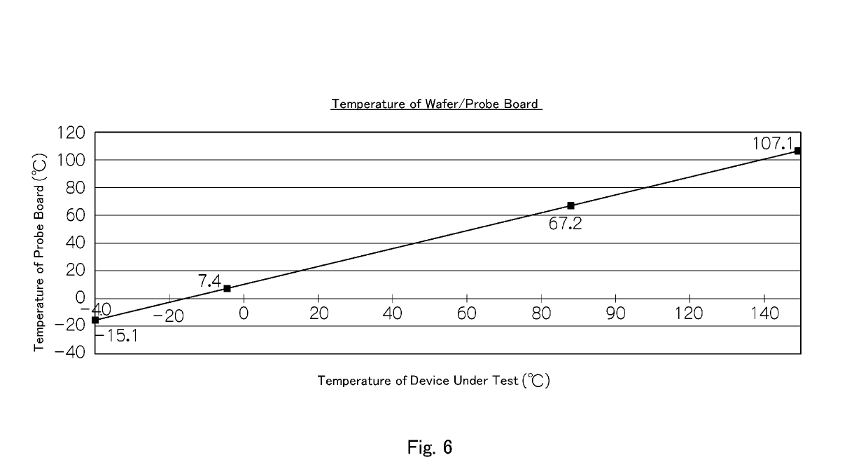

The temperature of the electrical connecting apparatus 10, particularly that of the probe board 26, varies as shown in FIG. 6, according to the temperature of the device under test 12. The higher the temperature of the device under test 12 is, the higher the temperature of electrical connecting apparatus 10 becomes. Also, the lower the temperature of the device under test 12, the lower than that of the electrical connecting apparatus 10 becomes.

For instance, when the device under test 12 is maintained at a temperature around +150° C., the electrical connecting apparatus 10 absorbs heat from the device under test 12 to rise in temperature. In the electrical connecting apparatus 10, however, the air moves through a gap between the probe board 26 and the device under test 12.

On the contrary, for instance, if the device under test 12 is maintained as low as −40° C., the temperature of the electrical connecting apparatus 10 lowers, as its heat is absorbed by the device under test 12. In the electrical connecting apparatus 10, however, the air moves through the gap between the probe board 26 and the device under test 12.

For this reason, even by heating or cooling the device under test 12, the probe board 26 is cooled or heated by the moving air, coupled with the fact that the coefficient of thermal expansion of the probe board 26 is greater than that of the device under test 12 by a value within from 1 ppm/° C. to 2 ppm/° C., and misregistration of the tip 54 due to change in temperature is restrained. Thus, the amount of misregistration of the tip 54 of each contact 46 relative to the connection terminal 14 of the device under test 12 is restrained, and the tip 54 of each contact 46 is prevented from coming off the connection terminal 14 of the device under test 12, thereby enabling an accurate test.

By an experiment, the position of the tip 54 of the contact 46 relative to the connecting portion 14 of the device under test 12 turned out as follows, provided that the connection terminal 14 has a rectangular shape, one side of which is 0.09 mm, and that the tip 54 has a rectangular shape, one side of which is 0.015 mm. Also, the support member 20 is made of stainless steel, and the thermal deformation restraining member 32 is made of aluminum.

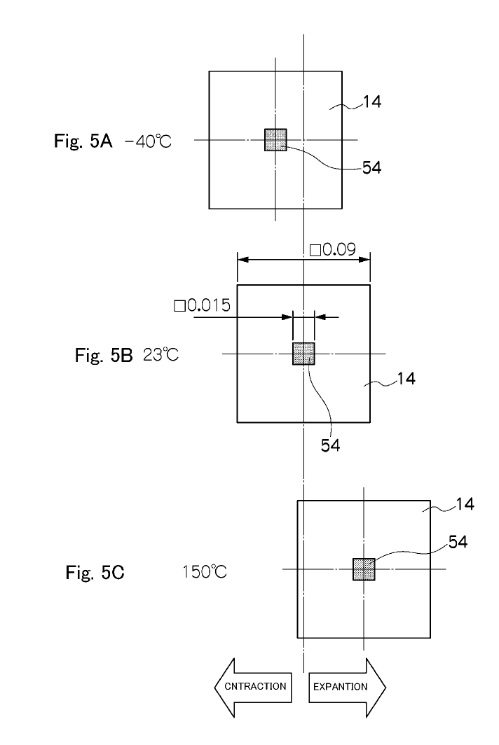

When the device under test 12 is maintained at +23° C. (room temperature), the tip 54 of the contact 46 is located, as shown in FIG. 5B, at the center of the connecting terminal 14 of the device under test 12.

On the other hand, if the device under test 12 is cooled to −40° C. from the aforementioned room temperature and maintained at the temperature, the electrical connecting apparatus 10, particularly, the probe board 26, is cooled to contract. Thus, as shown in FIG. 6A, the tip 54 of the contact 46 was deviated relative to the center of the connecting portion 14 of the device under test 12, but the tip 54 was not deviated.

Also, when the device under test 12 is heated to and maintained at +150° C. from the state of the above room temperature, the probe board 26 is heated to expand. As a result, the tip 54 of the contact 46 was deviated relative to the center of the connecting portion 14 of the device under test 12, as shown in FIG. 5C, but the tip 54 was not deviated from the connection terminal 14.

As mentioned above, if the distance L from the tip 54 of each contact 46 to the probe land 26b is set in the range from 1.1 mm to 1.3 mm and the coefficient of thermal expansion of the probe board 26 is increased by the range from 1 ppm/° C. to 2 ppm/° C. from that of the device under test 12, the following advantages are resulted.

Even if the device under test 12 is heated or cooled, misregistration of the tip 54 of each contact 46 due to a change in temperature of the probe board 26 is restrained, thereby restraining the amount of misregistration of the tip 54 of each contact 46 relative to the connection terminal 14 of the device under test 12. As a result, the tip 54 of each contact 46 is prevented from deviating from the connecting terminal 14 of the device under test 12, thereby enabling an accurate test.

When the distance from the tip 54 of the contact 46 to the probe land 26b is too short, the gap as mentioned above is not only too small but also the amount for the contact 46 to bend like an arc when an overdrive acts on the contact 46 becomes too small, so that an intended needle pressure (pressing force of the tip against the device under test) and the scraping amount of the oxide film by the tip 54 run short.

If the distance from the tip 54 of the contact 46 to the probe land 26b is too long, the contact 46 is deflexed largely in the lateral direction when an overdrive acts on the contact 46, and the tip 54 is deviated from the connection terminal 14 of the device under test 12.

Meanwhile, in the electrical connecting apparatus 10, the support member 20 serves to reinforce the wiring board 22 held on its underside 20a, but in test under a high-temperature environment, the central portion tends to have a convex deformation toward downward due to the weight of the electrical connector 24, the probe board 26 and the like.

In the electrical connecting apparatus 10, however, the thermal deformation restraining member 32 having the same coefficient of thermal expansion of the support member 20 or the coefficient of thermal expansion greater than that of the support member 20 is fixed on the support member 20 with the underside of the thermal deformation restraining member 32 brought into contact with the upside of the annular portion 20c with a plurality of male screw members 34. As a result, under a high-temperature environment, the thermal restraining member 32 tends to expand more greatly than the support member 20, but the underside of the thermal deformation restraining member 32 is restrained from extending by the support member 20 which is smaller in coefficient of thermal expansion than the thermal deformation restraining member 32.

Consequently, the upside to be a free plane of the thermal deformation restraining member 32 tends to extend more than the underside subjected to the restraint, so that, by the difference in stress, the central portion of the free plane generally tends to expand in a convex state so as to be away from the support member. The acting force due to this difference in stress acts as a force to restrain the downward convex deformation at the central portion of the support member.

As a result of a bimetal action such as above by the support member 20 and the thermal deformation restraining member 32, by providing the thermal deformation restraining member 32, it is possible to restrain the downward deflection due to the thermal expansion deformation of the support member 20 under a high-temperature environment and to restrain the flexural deformation of the probe board 26 accompanying the deflection of the support member 20.

As a wafer is large-sized, the dimension of a board such as the probe board 26 sometimes exceeds the outer diameter dimensions of the support member 20 and the thermal deformation restraining member 32. In such a case, by constituting the support member 20 and the thermal deformation restraining member 32 to do bimetal action, a large warping is caused by a difference in the coefficient of thermal expansion between both members 22 and 32.

When a large board such as above is used, warping due to thermal deformation can be restrained by making both members 22, 32 of materials having the same coefficient of thermal expansion, particularly, materials of the same quality, e.g., stainless steel, it is possible to make the electrical connecting apparatus large-sized.

### INDUSTRIAL APPLICABILITY

The present invention is not limited to the above embodiments but can be variously modified without departing from its purport.

What is claimed is:

1. An electrical connecting apparatus for electrically connecting a tester and electrical connection terminals of a device under test to undergo an electrical test by said tester, comprising:
a probe board having a plurality of probe lands on the underside; and a plurality of contacts each including a base end portion fixed on said probe land and a tip portion to be brought into contact with said connection terminal of the device under test;
wherein the distance from the tip of each contact to said probe land ranges from 1.1 mm to 1.3 mm; and
wherein the coefficient of thermal expansion of said probe board is greater than the coefficient of thermal expansion of said device under test within the range from 1 to 2 ppm/° C.

2. The electrical connecting apparatus claimed in claim 1, wherein said contact further includes an arm portion extending laterally from the lower end portion of said base end portion, and
wherein each tip portion of said contacts is projected downward from the arm portion.

3. The electrical connecting apparatus claimed in claim 1, further comprising: a wiring board on which a plurality of wiring circuits to be connected to said tester are firmed; an electrical connector disposed on the underside of said wiring board; and a support member disposed on said wiring board;
wherein said probe board is disposed on the underside of said electrical connector, and wherein said electrical connector has an electrical insulating plate disposed on the underside of said wiring board, and a plurality of connecting members arranged on said electrical insulating plate to electrically connect said wiring circuit of said wiring board and said contact.

4. The electrical connecting apparatus claimed in claim 1, wherein the coefficient of thermal expansion of said probe board ranges from 3 to 5 ppm/° C. when the coefficient of thermal expansion of said device under test ranges from 2 to 3 ppm/° C.
